(19) United States
(12) Patent Application Publication
(10) Pub. No.: US 2014/0131691 A1
(43) Pub. Date: May 15, 2014

(54) POLYMERIZABLE EPOXY COMPOSITION AND ORGANIC EL DEVICE

(71) Applicants: Yugo Yamamoto, Chiba-shi (JP); Masatoshi Takagi, Yokohama-shi (JP); Shunsuke Fujii, Ichihara-shi (JP); Shintaro Maekawa, Ichihara-shi (JP); Setsuko Oike, Yokohama-shi (JP)

(72) Inventors: Yugo Yamamoto, Chiba-shi (JP); Masatoshi Takagi, Yokohama-shi (JP); Shunsuke Fujii, Ichihara-shi (JP); Shintaro Maekawa, Ichihara-shi (JP); Setsuko Oike, Yokohama-shi (JP)

(73) Assignee: Mitsui Chemicals, Inc., Minato-ku, Tokyo (JP)

(21) Appl. No.: 14/130,699

(22) PCT Filed: Jul. 5, 2012
(86) PCT No.: PCT/JP2012/004380

§ 371 Date: Jan. 3, 2014

(30) Foreign Application Priority Data
Jul. 6, 2011 (JP) 2011-150124

(51) Int. Cl. H01L 23/29; H01L 51/52; H01L 51/50; H01L 27/32

(52) U.S. Cl. CPC H01L 23/293; H01L 27/3237; H01L 51/524; H01L 51/5012
USPC 257/40; 528/90; 438/28

(57) ABSTRACT

The purpose of the present invention is to provide a polymerizable resin composition with which the cured product refractive index is high and the viscosity under a high shear stress is a specific viscosity or lower. Provided is an polymerizable epoxy composition comprising (A1) an S-containing epoxy resin represented by a general formula, (A2) an epoxy compound having a softening point of 70° C. or lower, (B) a curing promoter, and (C) a thiol compound having two or more thiol groups per molecule, wherein viscosity at 25° C. and 60 rpm as determined using a B viscometer is between 100 and 15,000 mPa·s.

### TECHNICAL FIELD

The present invention relates to a polymerizable epoxy composition and an organic EL device.

### BACKGROUND ART

An organic EL element is promising as a next-generation display or an illumination apparatus due to its low power consumption and low dependence on view angle. The problem, however, is that an organic EL element is easily deteriorated with moisture or oxygen in the atmosphere. An organic EL element is therefore sealed with a sealing member for use.

Examples of the method for sealing an organic EL element include a method so called “frame sealing” and a method so called “face sealing.” In frame sealing, a structure has a sealing cap on an organic EL element arranged on a substrate, and the periphery of the sealing cap is sealed with a sealing member (refer to PTL 1 and the like). In face sealing, sealing is performed such that an organic EL element is covered. Examples of the method include a method for sealing a structure having a sealing plate on an organic EL element arranged on a substrate by filling a space between the sealing plate and the substrate and a space between the organic EL element and the sealing plate with a sealing material (refer to PTL 2 and the like).

It is believed that face sealing is effective when the panel size of an organic EL is large or light is extracted by a so-called top emission type. In the top emission type, the sealing member for face sealing is arranged at any position in the space formed between the organic EL element and the sealing plate. The sealing member is therefore required to have a high refractive index (small difference in refractive index between a transparent electrode and the sealing member). The reason for this is that a sealing member having a low refractive index causes total reflection between the electrode and the sealing member, resulting in low efficiency in extracting emission from an organic EL element.

The sealing material composition in face sealing by screen printing, dispensing, or the like is required to be in liquid form at approximately room temperature. A sealing material composition which is not in liquid form at approximately room temperature has a poor workability, requiring heating the sealing material composition to be melted during sealing of an organic EL element. Since the heating causes thermal strain in a display member, sufficient sealing is not always achieved. In addition, since heating the sealing material composition accelerates curing reaction, the viscosity tends to be unstable.

A light curing adhesive composition containing a thiol compound and an epoxy compound is proposed as an adhesive composition suitable for bonding optical components (refer to PTL 3 and the like). Since the light curing adhesive composition contains a large amount of elemental sulfur, it is believed that the cured product thereof has a high refractive index. Although a light curing adhesive composition has a low softening point with excellent workability at room temperature due to the absence of a rigid molecular structure such as a fluorene skeleton, it has a problem of low heat resistance.

A light curing adhesive containing an epoxy compound containing a sulfur atom and (meth)acrylic acid is proposed. It is reported that the adhesive has high adhesive force, high refractive index, and excellent heat resistance (refer to PTL 4). A curing resin composition containing an epoxy oligomer containing a sulfur atom and a compound copolymerizable therewith is also known. It is reported that the cured product thereof has a high refractive index (refer to PTL 5).

### CITATION LIST

### Patent Literature

### PTL1

Japanese Patent Application Laid-Open No. 11-45778

### PTL2

Japanese Patent Application Laid-Open No. 2001-357973

### PTL3

Japanese Patent Application Laid-Open No. 2004-35857

### PTL4

Japanese Patent Application Laid-Open No. 10-324858

### PTL5

Japanese Patent Application Laid-Open No. 8-183816

### SUMMARY OF INVENTION

### Technical Problem

Enhancement of the refractive index of the face sealing material of an organic EL element allows the efficiency in extraction of light of the organic EL device to be improved. In order to enhance the refractive index of the face sealing material, the electron density of a cured resin to constitute the face sealing material may be increased in general. In order to increase the electron density of a cured resin, a portion of the polymerization components of a resin polymerizable composition may include a sulfur-containing compound such as a thiol-containing compound.

A polymerizable resin compound for electronic materials is required to have formability. For example, a polymerizable resin compound is often applied to an organic EL element by printing coating such as screen printing in face sealing an organic EL element. Rapid application of a polymerizable resin composition under high shear stress is preferred in printing coating. A polymerizable resin composition having a viscosity at a predetermined level or lower is therefore preferred.

In order to reduce the viscosity of a polymerizable resin composition, for example, a solvent may be added. An organic solvent, however, may cause deterioration of precision electronic components such as an organic EL element. For example, an organic solvent in a polymerizable resin composition volatilizes as outgases under heating conditions and may cause deterioration of precision electronic components. On the other hand, an organic solvent having a high boiling point in a polymerizable resin composition remains in a cured product, causing difficulty in imparting desirable characteristics (e.g. refractive index) to the cured product.

Alternatively, in order to reduce the viscosity of a polymerizable resin composition, a low molecular weight component may be used as a portion of polymerization components. A low molecular weight component, however, has low compatibility with other polymerization components in some cases. This may cause a reduction in transparency (white turbidity) of a cured product. The viscosity of a polymerizable resin composition under high shear stress is easily affected by the combination of the respective components contained therein, so that a proper component is required to be selected.

On the other hand, an excessively low viscosity may cause a reduction in printability such as vague outlines in printing. An object of the present invention is therefore to provide a polymerizable resin composition having a viscosity at a predetermined level or lower under high shear stress, a cured product of which has a high refractive index.

### Solution to Problem

A first aspect of the present invention relates to the following polymerizable epoxy composition, a cured product thereof, and the like.

[1] A polymerizable epoxy composition which includes: (A1) a S-containing epoxy compound represented by the following general formula (i) having a refractive index of 1.66 to 1.80; (A2) an epoxy compound having a softening point of 70° C. or lower (except the (A1) S-containing epoxy compound); (B) a curing accelerator; and (C) a thiol compound having two or more thiol groups in one molecule; and has a viscosity of 100 to 15000 mPa·s at 25° C. and 60 rpm measured with a B type viscometer.

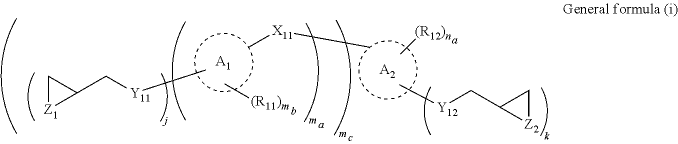

In general formula (i),

A₁ and A₂ each independently represent a benzene ring or a 1,3,5-triazine ring;

X₁₁ each independently represents —S—, —SO₂—, —O—, or —C(R₁₁)₂—, where R₁₁ each independently represents a hydrogen atom or a C₁₋₃ alkyl group;

Y₁₁ and Y₁₂ each independently represent —O— or —S—;

Z₁ and Z₂ each independently represent —O— or —S—;

R₁₁ and R₁₂ each independently represent a C₁₋₆ alkyl group or a halogen group;

mₐ represents any integer of 0 to 10;

m_{c} represents an integer of 1 to 5 when A₂ is a benzene ring, and represents 1 or 2 when A₂ is a 1,3,5-triazine ring;

m_{b} and nₐ each independently represent an integer of 0 to 4 when A₁ or A₂ is a benzene ring, and each independently represent 0 or 1 when A₁ or A₂ is a 1,3,5-triazine ring;

j and k each independently represent an integer of 1 to 5 when A₁ or A₂ is a benzene ring, and each independently represent 1 or 2 when A₁ or A₂ is a 1,3,5-triazine ring;

the sum of m_{b} and j is 5 or less when A₁ is a benzene ring, and 2 or less when A₁ is a 1,3,5-triazine ring;

the sum of nₐ, k, and m_{c} is 6 or less when A₂ is a benzene ring, and 3 or less when A₂ is a 1,3,5-triazine ring;

at least one group represented by Y₁₁, Y₁₂, Z₁, and Z₂ is —S— when mₐ is 0; and

at least one group represented by X₁₁, Y₁₁, Y₁₂, Z₁, and Z₂ is a S-containing group when mₐ is 1 to 10.

[2] The polymerizable epoxy composition described in [1], in which the S-containing epoxy compound represented by general formula (i) is a S-containing epoxy compound represented by the following general formula (1).

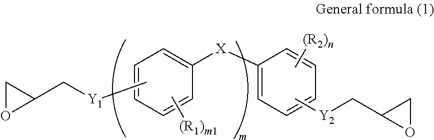

In general formula (1),

X represents —S— or —SO₂—;

Y₁ and Y₂ each independently represent —O— or —S—;

m represents any integer of 0 to 10;

ml and n each independently represent any integer of 0 to 4;

R₁ and R₂ each independently represent a C₁₋₆ alkyl group or a halogen group; and

at least one of Y₁ and Y₂ is —S— when m is 0.

[3] The polymerizable epoxy composition described in [1] or [2], further including (A3) a fluorene epoxy compound represented by the following general formula (2) or general formula (3).

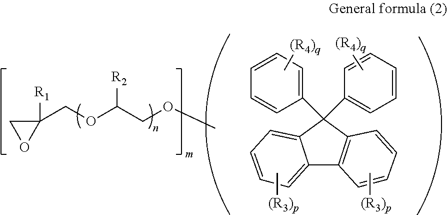

In general formula (2),

R₁ each independently represents a hydrogen atom or a methyl group;

R₂ each independently represents a hydrogen atom or a methyl group;

R₃ each independently represents a C₁₋₅ alkyl group;

R₄ each independently represents a C₁₋₅ alkyl group;

m represents an integer of 2 or more;

n each independently represents an integer of 0 to 3;

p each independently represents an integer of 0 to 4; and

q each independently represents an integer of 0 to 5.

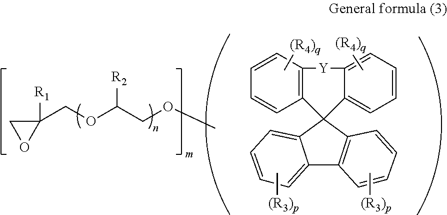

In general formula (3),

Y represents a single bond, an oxygen atom, or a sulfur atom;

q each independently represents an integer of 0 to 4; and

R₁ to R₄, m, n, and p are defined as in general formula (2).

[4] The polymerizable epoxy composition described in any one of [1] to [3], in which the (A2) epoxy compound is at least one epoxy compound selected from the group consisting of a bisphenol A epoxy compound, a bisphenol F epoxy compound, an amino epoxy compound, and an epoxy compound represented by the following general formula (4).

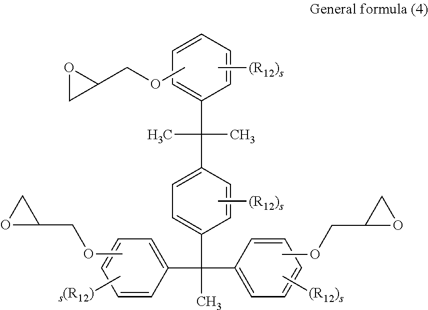

In general formula (4),

R₁₂ each independently represents a C₁₋₅ alkyl group or a halogen atom; and

s represents 0 to 4.

[5] The polymerizable epoxy composition described in any one of [1] to [4], in which the (A2) epoxy compound is a trifunctional epoxy compound.

[6] The polymerizable epoxy composition described in any one of [1] to [5], in which the (C) thiol compound has a thiol equivalent of 80 to 100 g/eq and a sulfur content rate of 50 to 80%.

[7] The polymerizable epoxy composition described in [6], in which the (C) thiol compound has a molecular weight of 140 to 500.

[8] The polymerizable epoxy composition described in any one of [1] to [7], in which the content of the (A1) S-containing epoxy compound is 50 parts by mass or more relative to 100 parts by mass of the epoxy compounds contained in the polymerizable epoxy composition.

[9] The polymerizable epoxy composition described in any one of [1] to [8], in which a molar ratio of an epoxy group and a thiol group contained in the polymerizable epoxy composition is 1:0.9 to 1.1.

[10] The polymerizable epoxy composition described in any one of [1] to [9], having a water content rate of 0.1% by mass or less.

[11] A transparent resin for use in optical material, including a polymerizable epoxy composition described in any one of [1] to [10].

[12] A face sealing agent for an organic EL element, including a polymerizable epoxy composition described in any one of [1] to [10].

[13] A cured product of a polymerizable epoxy composition described in any one of [1] to [10], having a refractive index of 1.68 or higher.

A second aspect of the present invention relates to the following organic EL device, manufacturing method thereof, and the like.

[14] An organic EL device including a display substrate having an organic EL element thereon, a counter substrate to constitute a pair with the display substrate, and a sealing member that is interposed between the display substrate and the counter substrate and is filled in the space formed between the organic EL element and the counter substrate, in which the sealing member is a cured product of the polymerizable epoxy composition described in any one of [1] to [10].

[15] An organic EL device including an organic EL element, a sealing member in contact with the organic EL element, and a passivation membrane in contact with the sealing member, in which the sealing member is a cured product of a polymerizable epoxy composition described in any one of [1] to [10].

[16] An organic EL display panel having an organic EL device described in [14] or [15].

[17] A manufacturing method of an organic EL device including: a first step of forming an organic EL element on a display substrate; a second step of sealing the organic EL element with the composition described in any one of [1] to [10]; a third step of laminating a counter substrate on the display substrate through the composition; and a fourth step of curing the composition to form a sealing part.

[18] A manufacturing method of an organic EL device including: a first step of forming an organic EL element on a substrate; a second step of sealing the organic EL element with a composition described in any one of [1] to [10]; a third step of curing the composition to form a sealing part; and a fourth step of forming a passivation membrane on the sealing part.

Advantageous Effects of Invention

A polymerizable epoxy composition of the present invention can be formed into a cured product with good workability. The cured product has a high refractive index. Consequently the polymerizable epoxy composition of the present invention is suitable in particular for use in forming a membrane of face sealing material for an optical device, in particular for a light emitting device.

### BRIEF DESCRIPTION OF DRAWINGS

FIGS. 1A and 1B illustrate the structure of an organic EL device;

FIGS. 2A to 2E illustrate the production flow of an organic EL device; and

FIG. 3 is a graph plotted between the viscosity of polymerizable epoxy compositions obtained in Examples versus Comparative Examples and the refractive index of the cured products thereof.

### DESCRIPTION OF EMBODIMENTS

1. Polymerizable Epoxy Composition

The polymerizable epoxy composition of the present invention includes (A1) a S-containing epoxy compound, (A2) a low softening point epoxy compound having a low softening point (except (A1)), (B) a curing accelerator, and (C) a thiol compound. The composition may further include (A3) a fluorene epoxy compound.

The (A1) S-containing epoxy compound is represented by the following general formula (i). In the present specification, “an epoxy group” includes “a thioepoxy group.” The (A1) S-containing epoxy compound also includes a thioepoxy compound having a thioepoxy group.

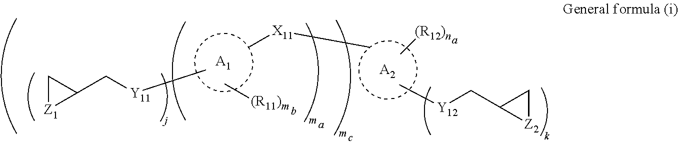

In general formula (i), A₁ and A₂ each independently represent a benzene ring or a 1,3,5-triazine ring;

X₁₁ each independently represents —S—, —SO₂—, —O—, or —C(R₂₁)₂— (R₂₁ each independently represents a hydrogen atom or a C₁₋₃ alkyl group) and when a plurality of X₁₁ are contained, X₁₁ each may be the same or different.

R₁₁ and R₁₂ each independently represent a C₁₋₆ alkyl group or a halogen group. The C₁₋₆ alkyl group may be a straight or branched alkyl group, such as methyl, ethyl, n-propyl, iso-propyl, n-butyl, sec-butyl, tert-butyl, pentyl, and hexyl. Examples of the halogen group include chlorine, bromine, and iodine.

Herein, m_{b} and nₐ each represent the numbers of R₁₁ and R₁₂, and independently represent any integer of 0 to 4, preferably 0. With large m_{b} and nₐ, the softening point of the (A1) S-containing epoxy compound is lowered, resulting in improved workability in forming a membrane of a polymerizable epoxy composition. On the other hand, the heat resistance and refractive index of the cured product of a polymerizable epoxy composition may be excessively lowered in some cases.

Herein, mₐ represents any integer of 0 to 10, preferably 1.

Herein, m_{c} represents an integer of 1 to 5 when A₂ is a benzene ring, and represents 1 or 2 when A₂ is a 1,3,5-triazine ring. With a large m_{c}, the number of epoxy group (including thioepoxy group) in the compound of general formula (i) increases so as to enhance the heat resistance of the cured product of a polymerizable epoxy composition. On the other hand, the curing shrinkage rate may excessively increase in some cases.

Y₁₁ and Y₁₂ each independently represent —O— or —S—. Z₁ and Z₂ each independently represent —O— or —S—.

Herein, j and k each independently represent an integer of 1 to 5. With large j and k, the heat resistance of the cured product of a polymerizable epoxy composition is enhanced. On the other hand, the curing shrinkage rate may excessively increase in some cases.

Herein, at least one group represented by Y₁₁, Y₁₂, Z₁, and Z₂ is —S— when all of mₐ included in general formula (i) is 0. On the other hand, at least one group represented by X₁₁, Y₁₁, Y₁₂, Z₁, and Z₂ includes S when any one of mₐ included in general formula (i) is 1 to 10. In other words, at least one of Y₁₁, Y₁₂, Z₁, and Z₂ is —S—, or X₁₁ is —S— or —SO₂—. Namely, the compound represented by general formula (i) inevitably includes a S atom.

The sum of nₐ, k, and m_{c} is 6 or less when A₂ is a benzene ring, and 3 or less when A₂ is a 1,3,5-triazine ring. The sum of m_{b} and j in a phenyl group bound with a group represented by the following formula in general formula (i) is 5 or less.

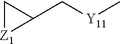

A compound represented by general formula (i) has a refractive index of 1.66 to 1.80. When the (A1) S-containing epoxy compound represented by general formula (i) has a refractive index of 1.66 or higher, the refractive index of the cured product of a polymerizable epoxy composition is enhanced. The refractive index is a measured value using the sodium D line (589 nm). The refractive index can be measured with a known method. In general, the refractive index can be measured by a critical angle method with an Abbe refractometer.

Examples of the S-containing epoxy compound represented by general formula (i) include compounds represented by the following general formulae (ii) to (iv).

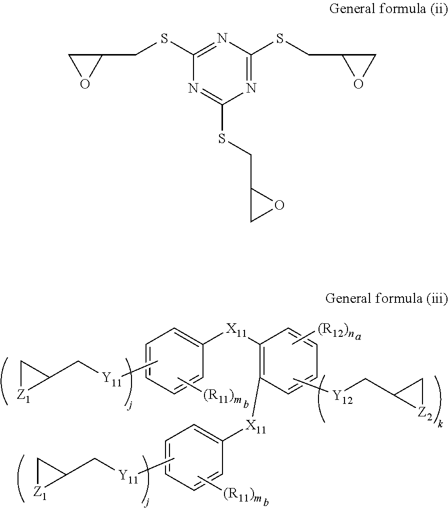

In general formula (iii), R₁₁, R₁₂, X₁₁, Y₁₁, Y₁₂, Z₁, Z₂, m_{b}, nₐ, j, and k are the same as in general formula (i).

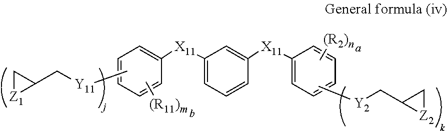

In general formula (iv), R₁₁, R₁₂, X₁₁, Y₁₁, Y₁₂, Z₁, Z₂, m_{b}, nₐ, j, and k are the same as in general formula (i).

Examples of the specifically preferred S-containing epoxy compound represented by general formula (i) include a S-containing epoxy compound represented by the following general formula (1).

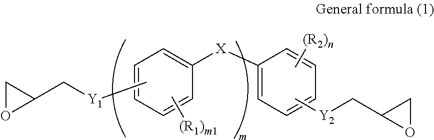

In general formula (1), X represents —S— or —SO₂—. Y₁ and Y₂ each independently represent —O— or —S—. Herein, m represents any integer of 0 to 10, preferably 1. When m is 0, at least one of Y₁ and Y₂ is —S—. In other words, a compound represented by general formula (1) inevitably includes a S atom.

R₁ and R₂ each independently represent a C₁₋₆ alkyl group or a halogen group. The C₁₋₆ alkyl group may be a straight or branched alkyl group, such as methyl, ethyl, n-propyl, iso-propyl, n-butyl, sec-butyl, tert-butyl, pentyl, and hexyl. Examples of the halogen group include chlorine, bromine, and iodine. Herein, ml and n each independently represent any integer of 0 to 4, preferably 0.

Specific examples of the S-containing epoxy compound represented by general formula (1) include bis[4-(2,3-epoxypropylthio)phenyl]sulfide, bis[4-(2,3-epoxypropylthio)-3-methylphenyl]sulfide, bis[4-(2,3-epoxypropylthio)-3,5-dimethylphenyl]sulfide, bis[4-(2,3-epoxypropylthio)-2,3,5,6-tetramethylphenyl]sulfide, bis[4-(2,3-epoxypropylthio)-3-hexylphenyl]sulfide, bis[4-(2,3-epoxypropylthio)-3,5-dihexylphenyl]sulfide, bis[4-(2,3-epoxypropylthio)-3-chlorophenyl]sulfide, bis[4-(2,3-epoxypropylthio)-3,5-dichlorophenyl]sulfide, bis[4-(2,3-epoxypropylthio)-2,3,5,6-tetrachlorophenyl]sulfide, bis[4-(2,3-epoxypropylthio)-3-bromophenyl]sulfide, bis[4-(2,3-epoxypropylthio)-3,5-dibromophenyl]sulfide, and bis[4-(2,3-epoxypropylthio)-2,3,5,6-tetrabromophenyl]sulfide.

Specific examples of preferred S-containing epoxy compound represented by general formula (1) include bis[4-(2,3-epoxypropylthio)phenyl]sulfide, bis[4-(2,3-epoxypropylthio)-3-methylphenyl]sulfide, bis[4-(2,3-epoxypropylthio)-3,5-dimethylphenyl]sulfide, and bis[4-(2,3-epoxypropylthio)-3,5-dibromophenyl]sulfide.

A manufacturing method of the (A1) S-containing epoxy compound is not specifically limited. For example, the S-containing epoxy compound represented by general formula (ii) is obtained through reaction of a trithiol compound of the following formula and epihalohydrin.

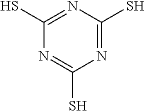

The S-containing epoxy compound represented by general formula (1) is obtained, for example, through reaction of a dithiol compound or a diol compound of the following formula (X, Y₁, Y₂, m, R₁, R₂, ml, and n are defined as in general formula (1)) and epihalohydrin.

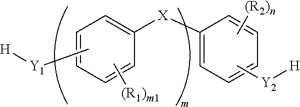

The (A1) S-containing epoxy compound allows the refractive index of the cured product of a polymerizable epoxy composition to be easily increased. Yet, since the viscosity of the compound is not excessively high, the viscosity of the polymerizable epoxy composition is not increased more than necessary. Furthermore, the compound has excellent compatibility with the (A2) low softening point epoxy compound to be described or the like.

The polymerizable epoxy composition of the present application has low viscosity even under high shear stress. For example, in the (A1) S-containing epoxy compound represented by general formula (i), X₁₁ is a relatively short cross-linking part, and Y₁₁ and Y₁₂ are also short cross-linking parts, even when m_{c} and mₐ are 1 or more. The flexibility in conformation of ring A₁, ring A₂, and an epoxy group (thioepoxy group) is thus low, so that the (A1) S-containing epoxy compound tends to have a compact structure. Since ring A₁ and ring A₂ are relatively small rings such as a benzene ring and a 1,3,5-triazine ring, the (A1) S-containing epoxy compound has a low volume. It is therefore believed that the polymerizable epoxy composition can maintain low viscosity even under high shear stress. Furthermore, since the polymerizable epoxy composition has rings A₁ and A₂ of a certain number or more in one molecule, the compatibility with the (A2) low softening point epoxy compound (compound having a benzene ring, in particular) and the (A3) fluorene epoxy compound to be described is high. This allows the cured product of the polymerizable epoxy composition to have high transparency.

The (A2) low softening point epoxy compound has a softening point of preferably 70° C. or lower, and may be in a liquid form at room temperature. In the present specification, the (A2) low softening point epoxy compound includes no (A1) S-containing epoxy compound. The (A2) epoxy compound having a low softening point can further improve the workability of the polymerizable epoxy composition. The (A2) low softening point epoxy compound has excellent compatibility with components such as the (A1) S-containing epoxy compound. This also has effect to prevent the cured product of the composition of the present invention from producing white turbidity. The softening point is measured by the ring and ball method (according to JIS K7234).

The (A2) low softening point epoxy compound is not specifically limited, including a bisphenol A epoxy compound, a bisphenol F epoxy compound, an amino epoxy compound, and an epoxy compound represented by the following general formula (4).

The bisphenol A epoxy compound and the bisphenol F epoxy compound can be represented by the following formulae, respectively. In the formulae, R₁₀ each independently represents a C₁₋₅ alkyl group, preferably a methyl group; p represents the number of substitution of substituent group R₁₀, which is 0 to 4, preferably 0.

### Bisphenol A Epoxy Compound

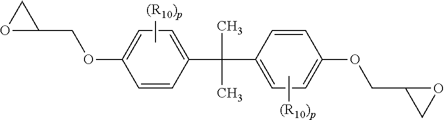

### Bisphenol F Epoxy Compound

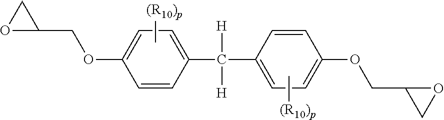

An amino epoxy compound is typically, for example, the following aniline-type epoxy compound. Examples of the aniline-type epoxy compound include the following compound. In the formula, R₁₁ represents a C₁₋₅ alkyl group or a halogen atom, q is 0 to 5, and r is 0 to 4.

### Aniline-Type Epoxy Compound

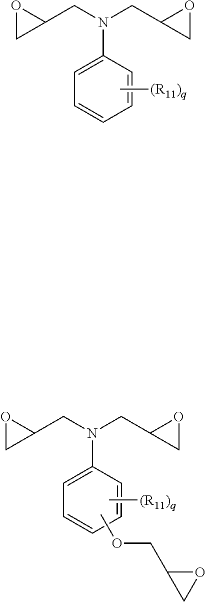

In general formula (4), R₁₂ each independently represents a C₁₋₅ alkyl group or a halogen atom, and s is 0 to 4.

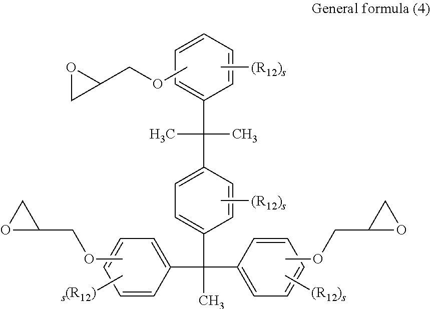

At least a portion of the (A2) epoxy compounds having a low softening point is preferably a trifunctional epoxy compound. A trifunctional epoxy compound can increase the degree of cross-linkage of the cured product of a polymerizable epoxy composition, so that the heat resistance of the cured product can be enhanced.

The (A3) fluorene epoxy compound allows the cured product of a polymerizable resin composition that contains the compound to have an increased refractive index. Since fluorene is a rigid aromatic group, the cured product of a polymerizable epoxy composition that contains a fluorene epoxy compound has an increased glass transition temperature Tg. The heat resistance of the cured product is thus increased.

The (A3) fluorene epoxy compound has a softening point of preferably 50° C. to 200° C., more preferably 80° C. to 160° C. The reason is that the workability of the composition of the present invention is improved and the heat resistance of the cured product is enhanced. The inclusion of the (A3) component also allows for improved plasma resistance and weather resistance.

The fluorene epoxy compound is represented by general formula (2) or (3).

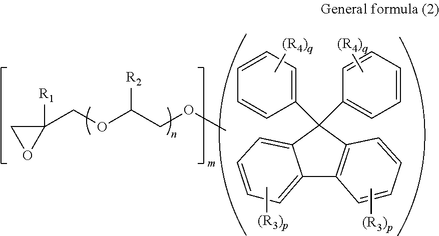

In general formula (2), R₁ each independently represents a hydrogen atom or a methyl group. A hydrogen atom is preferred in order to enhance the reactivity of an epoxy group. In general formula (2), R₂ each independently represents a hydrogen atom or a methyl group. A hydrogen atom is preferred due to excellence in the reactivity of an epoxy group.

In general formula (2), n represents the number of repetition of an alkylene ether unit. Herein, n each is independently an integer of 0 to 3. The larger the n is, the lower the softening point of a compound, so that the workability of a resin composition can be improved as described later. An excessively large n, however, may cause reduction in heat resistance of the cured product thereof. Preferably n is therefore 0 or 1.

In general formula (2), m represents the number of substitution of an epoxy group-containing substituent group, which is an integer of 2 or more, and usually 4 or less. An “epoxy group-containing substituent group” means a substituent group which is bound to a benzene ring and contains an epoxy group. An epoxy group-containing substituent group may be bound to any benzene ring. With a large m, the cured product has excellent heat resistance. The curing shrinkage rate, however, may increase too much in some cases. Preferably m is therefore 2.

In general formula (2), p represents the number of substitution of R₃. Herein p each is independently an integer of 0 to 4. With a large p, the softening point is lowered, so that the workability can be improved. The cured product, however, may have excessively lowered heat resistance and refractive index in some cases. Preferably p is therefore 0 or 1, more preferably 0. In general formula (2), R₃ each independently represents a C₁₋₅ alkyl group. With a large carbon number, the softening point is lowered, so that the workability can be improved. The cured product, however, may have excessively lowered heat resistance and refractive index in some cases. Preferably R₃ is therefore a methyl group.

In general formula (2), q represents the number of substitution of R₄. Herein q each is independently an integer of 0 to 5. With a large q, the softening point is lowered, so that the workability can be improved. The cured product, however, may have excessively lowered heat resistance and refractive index in some cases. Preferably q is therefore 0 or 1, more preferably 0. In general formula (2), R₄ each independently represents a C₁₋₅ alkyl group. With a large carbon number, the softening point is lowered, so that the workability can be improved. The cured product, however, may have excessively lowered heat resistance and refractive index in some cases. Preferably R₄ is therefore a methyl group.

The fluorene epoxy compound represented by general formula (2) is preferably a compound represented by the following general formula (2-1).

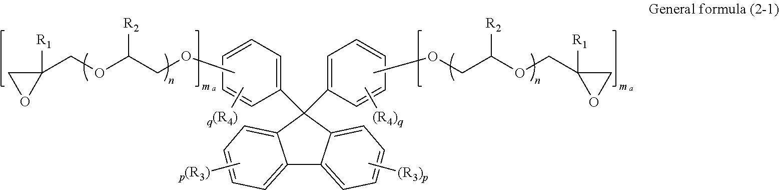

In general formula (2-1), mₐ each independently represents an integer of 1 to 3, preferably 1. In general formula (2-1), q each independently represents an integer of 0 to 4. In general formula (2-1), R₁ to R₄, n, and p are defined as in general formula (2).

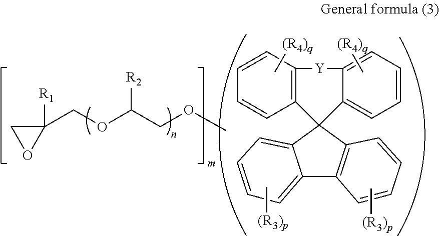

In general formula (3), Y represents a single bond, an oxygen atom, or a sulfur atom. In general formula (3), q each independently represents an integer of 0 to 4. In general formula (3), R₁ to R₄, m, n, and p are defined as in general formula (2).

The fluorene epoxy compound represented by general formula (3) is preferably a compound represented by the following general formula (3-1).

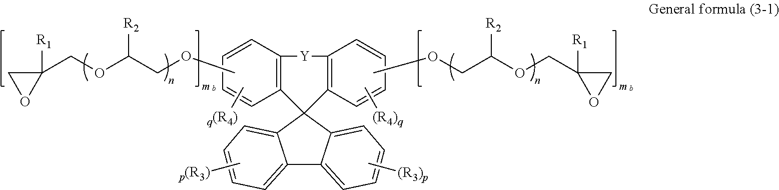

In general formula (3-1), m_{b} each independently represents an integer of 1 to 3, preferably 1. In general formula (3-1), q each independently represents an integer of 0 to 3. In general formula (3-1), R₁ to R₄, n, and p are defined as in general formula (3).

A compound represented by general formula (3) has a more rigid molecular structure compared with the molecular structure of a compound represented by general formula (2). The cured product of a compound represented by general formula (3) has therefore high heat resistance. In particular, the heat resistance of the cured product is significantly improved when Y is a single bond. The workability may, however, be reduced due to an excessively high softening point in some cases. On the other hand, an excellent balance therebetween is achieved when Y is an oxygen atom or a sulfur atom.

The (A3) fluorene epoxy compound can be obtained, for example, through reaction of phenol having a fluorene skeleton and epichlorohydrin (also referred to as “3-chloro-1,2-epoxy propane”) by a known method. A desired epoxy compound can be synthesized by proper selection of the structures of epichlorohydrin and phenol having a fluorene skeleton. Namely, using a derivative of epichlorohydrin as raw material instead of epichlorohydrin, R₁ in general formula (2) can be properly changed. For example, using an epichlorohydrin derivative in which position 2 of 3-chloro-1,2-epoxy propane is substituted by a methyl group as raw material, a fluorene epoxy compound having a methyl group as R₁ in general formula (2) can be synthesized.

A phenol having a fluorene skeleton can be synthesized according to a method described in Japanese Patent Application Laid-Open No. 2001-206862. Through selection of the skeleton of a phenol having a fluorene skeleton, m, R₃, and p in general formula (2) can be properly changed. Using a multi-functional hydroxyl group-containing fluorene compound described in PTL 3 as raw material, a fluorene epoxy compound having a hydrogen atom or a methyl group as R₂ and n other than zero in general formula (2) can be synthesized.

As described above, a polymerizable epoxy composition of the present invention includes the (A1) S-containing epoxy compound and the (A2) low softening point epoxy compound, and further includes the (A3) fluorene epoxy compound in a more preferable aspect. The content of the (A1) component is preferably 50 parts by mass or more relative to 100 parts by mass of the total content of the (A1) S-containing epoxy compound and the (A2) epoxy compound having a low softening point in the polymerizable epoxy composition, or the total content of the (A1) component, the (A2) component, and the (A3) component when the (A3) fluorene epoxy compound is contained. In order to increase the refractive index of the cured product of a polymerizable epoxy composition, preferably the content of the (A1) S-containing epoxy compound is increased. More specifically, the refractive index of the cured product can be easily adjusted to 1.68 or higher, with the content of the (A1) S-containing epoxy compound of 50 parts by mass or more.

When the composition of the present invention includes the (A3) fluorene epoxy compound, the content of the (A3) fluorene epoxy compound is preferably 1 to 60 parts by weight, more preferably 5 to 50 parts by weight, and further preferably 10 to 30 parts by weight, relative to 100 parts by mass of the total contents of the (A1) component, the (A2) component, and the (A3) component. With the content of the (A3) fluorene epoxy compound in the range, the heat resistance, plasma resistance, and weather resistance of the cured product of a polymerizable epoxy composition can be improved.

(B) Curing Accelerator

Examples of the (B) curing accelerator for accelerating curing of an epoxy compound include an imidazole compound and an amine compound. Examples of the imidazole compound include 2-ethyl-4-methyl imidazole. Examples of the amine compound include tris[dimethylamino)methyl]phenol. The (B) curing accelerator may be a Lewis base compound. For the use of the polymerizable epoxy composition of the present invention in sealing agent for a light emitting element, in particular, for an organic EL element, the (B) curing accelerator is preferably a thermosetting accelerator. In that case, preferably the composition of the present invention includes substantially no light curing accelerator. The reason is that a light curing accelerator decomposes and generates a gas or the like which deteriorates a light emitting element during acceleration of curing in many cases, compared with a thermosetting accelerator.

The content of the (B) curing accelerator in a polymerizable epoxy composition is preferably 0.1 to 5 parts by mass relative to 100 parts by mass of the total epoxy compounds. The reason is that the balance between the curability and the storage stability of a polymerizable epoxy composition is excellent.

(C) Thiol Compound

The (C) thiol compound has two or more thiol groups in one molecule as a feature. The (C) thiol compound can act as a curing agent of an epoxy compound. Namely, the thiol group of the (C) thiol compound reacts with the epoxy group (including the thioepoxy group) of epoxy compounds, so that the epoxy compounds are cross-linked to each other to produce a cured product having excellent heat resistance, adhesive strength, and the like. The thiol compound can also improve transparency of the cured product of a polymerizable epoxy composition. The reason is supposed that the (C) thiol compound allows the epoxy compounds to be cross-linked so that benzene rings or 1,3,5-triazine rings in the epoxy compounds are prevented from being accumulated. From the viewpoint of improving transparency of the cured product, the (C) thiol compound is preferably a compound including no benzene ring or no 1,3,5-triazine ring.

The (C) thiol compound may have two or more thiol groups in one molecule, and is not specifically limited. With a large number of thiol groups, the cross-linkage density of the cured product of an epoxy composition to be produced (hereinafter simply referred to as “cured product” in some cases) is increased, so that the heat resistance of the cured product is improved. With an excessively large number of thiol groups, the presence of thiol groups closely positioned each other in a molecule of thiol compound easily causes steric hindrance, resulting in reduced reactivity with an epoxy group (including a thioepoxy group). The content of thiol groups in one molecule is represented in thiol equivalent (g/eq).

The (C) thiol compound has a thiol equivalent of 80 to 100 g/eq, preferably 85 to 95 g/eq, more preferably 86 to 92 g/eq. The thiol equivalent is a value of the molecular weight of the (C) thiol compound divided by the number of thiol groups included in the molecule. With a thiol equivalent of less than 80 g/eq, the distance between cross-linked points of the cured product is shortened, so that the reactivity with an epoxy group (including a thioepoxy group) is reduced. The conversion rate is, therefore, not raised in some cases. On the other hand, with a thiol equivalent of more than 100 g/eq, the distance between cross-linked points of the cured product is excessively extended, so that the heat resistance of the cured product is reduced in some cases.

The (C) thiol compound may includes a sulfur atom other than a thiol group in the molecule. A thiol compound which contains a sulfur atom in the molecule allows the refractive index of the cured product of a polymerizable epoxy composition to be increased. The sulfur content rate of the (C) thiol compound in a polymerizable epoxy composition is therefore 50 to 80%, preferably 60 to 75%.

The sulfur content rate is obtained from the proportion of each element (proportion of elemental sulfur in entire elements) by mass analysis of a thiol compound. The refractive index of the cured product of a resin composition including the thiol compound with a sulfur content rate of less than 50% is not sufficiently increased in some cases. The thiol compound with a sulfur content rate of more than 80% includes a S—S bond in a molecule in many cases. The cured product of a resin composition including the same may generate a radical or have poor chemical stability in some cases.

The molecular weight of the (C) thiol compound is preferably 140 to 500. The (C) thiol compound with a high molecular weight may have excessively high viscosity, or may cause non-uniform curing in some cases. The molecular weight may be obtained by mass analysis.

The (C) thiol compound is not specifically limited, so long as the thiol equivalent and the sulfur content rate are in the ranges. Specific examples of the (C) thiol compound include compounds represented by the following formulae (4), (5), and (6). The compounds represented by formulae (4), (5), and (6) can be synthesized by a known method or are commercially supplied. The compound of formula (4) has a thiol equivalent of 87 g/eq, and a sulfur content rate of 62%. The compound of formula (5) has a thiol equivalent of 91 g/eq, and a sulfur content rate of 61%. The compound of formula (6) has a thiol equivalent of 89 g/eq, and a sulfur content rate of 72%.

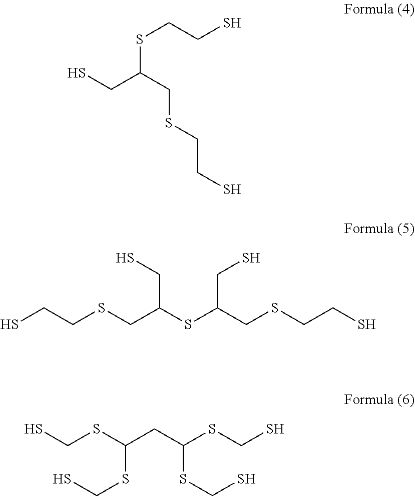 [SMILES: SCCSCC(CS)SCCS ; SCCSCC(CS)SC(CS)CSCCS ; SCSC(CC(SCS)SCS)SCS]

Although the content of the (C) thiol compound in the polymerizable epoxy composition of the present invention is not specifically limited, the content may be determined by the molar ratio between the thiol group and the epoxy group (including thioepoxy group) contained in a polymerizable epoxy composition in some cases. The reason is that the (C) thiol compound acts as a curing agent of an epoxy compound. When a polymerizable epoxy composition includes excessive thiol groups, the thiol groups unreacted with an epoxy group (including a thioepoxy group) remain in the cured product. This may cause contamination of a member in the vicinity of the cured product. On the other hand, an excessively small amount of thiol groups cannot sufficiently increase the cross-linkage density, so that the heat resistance of the cured product to be produced is reduced in some cases.

For example, relative to 1 mole of an epoxy group (including thioepoxy group) contained in the polymerizable epoxy composition of the present invention, preferably 0.9 to 1.1 moles of a thiol group is contained, more preferably 0.95 to 1.05 moles of a thiol group is contained, and particularly preferably 1 mole of a thiol group is contained.

(D) Silane Coupling Agent

The (D) silane coupling agent may be included in a polymerizable epoxy composition. A polymerizable epoxy composition which includes the (D) silane coupling agent has high adhesion with a substrate or the like when used as a composition for organic EL sealing material. Examples of the (D) silane coupling agent include a silane compound having a reactive group such as an epoxy group, a carboxyl group, a methacryloyl group, and an isocyanate group. Specific examples of the silane compound include trimethoxysilyl=benzoate, γ-methacryloxy propyl trimethoxysilane, vinyl triacetoxysilane, vinyl trimethoxysilane, γ-isocyanatopropyl triethoxysilane, γ-glycidoxypropyl trimethoxysilane, and β-(3,4-epoxycyclohexyl)ethyl trimethoxysilane. The silane coupling agent may be used singly, or in combinations of two or more.

The content of the (D) silane coupling agent in a polymerizable epoxy composition is preferably 0.05 to 30 parts by mass, more preferably 0.1 to 20 parts by mass, further preferably 0.3 to 10 parts by mass relative to 100 parts by mass of the polymerizable epoxy composition.

(E) Other Optional Component

The polymerizable epoxy composition may further contain an optional component such as any other resin component, a filler, a modifier, and stabilizer within the range not impairing the effect of the present invention. Examples of the other resin component include polyamide, polyamide imide, polyurethane, polybutadiene, polychloroprene, polyether, polyester, a styrene-butadiene-styrene block copolymer, a petroleum resin, a xylene resin, a ketone resin, a cellulose resin, a fluorine oligomer, a silicone oligomer, and a polysulfide oligomer. A single one of these or a combination of a plurality of these may be contained.

Examples of the filler include glass beads, styrene polymer particles, methacrylate polymer particles, ethylene polymer particles, and propylene polymer particles. A combination of a plurality of fillers may be used. Examples of the modifier include a polymerization initiation aid, an antiaging agent, a leveling agent, a wettability improving agent, a surfactant, and a plasticizer. A combination of a plurality of these may be used. Examples of the stabilizer include a UV-absorbing agent, an antiseptic agent, and an antibacterial agent. A combination of a plurality of modifiers may be used.

When transparency is required for the cured product of the composition of the present invention, preferably a component which causes phase separation with an epoxy compound and has a large refractive index difference between an epoxy compound and the component is not substantially included. More specifically, such a component is an inorganic filler or organic filler having a refractive index difference between the cured product of an epoxy compound and the component of 0.1 or more and a diameter of 0.1 μm or more.

The water content rate of the polymerizable epoxy composition of the present invention particularly for use in a sealing agent for a light emitting element is preferably 0.1% by mass or less, more preferably 0.06% by mass or less. Since an electric circuit having an organic EL element itself or a light emitting element is easily deteriorated with moisture, the water content rate of the polymerizable epoxy composition is preferably reduced as low as possible. The water content rate of the polymerizable epoxy composition can be obtained by weighing an approximately 0.1 g of sample, heating the sample to 150° C. with a Karl Fischer moisture titrator, and measuring the amount of generated moisture (solid vaporizing method).

Considering the easiness of application work and the like, the polymerizable epoxy composition of the present invention has a viscosity at 25° C. of, preferably 100 to 15000 mPa·s, more preferably 100 to 10000 mPa·s, further preferably 100 to 6000 mPa·s. The viscosity at 25° C. of the composition is measured at a rotation speed of 60 rpm with a B type viscometer (BL type, made by Toki Sangyo Co., Ltd). The viscosity measured at a high rotation speed (60 rpm) is adjusted, such that printing workability in screen printing or the like can be improved. The reason is that a shear stress is applied to the resin composition as application material in screen printing.

It is preferred that the polymerizable epoxy composition of the present invention has a small curing shrinkage rate. Preferably the curing shrinkage rate is 10% or less, more preferably 8% or less. The curing shrinkage rate can be obtained by applying the specific gravity of the composition before curing and the specific gravity of the cured product after curing into the following equation.

Curing shrinkage rate (%)={(specific gravity of cured product−specific gravity of uncured composition)/specific gravity of cured product}×100

It is important that the sealing material composition for making a sealing member for face sealing has a low curing shrinkage rate. The reason is that a high curing shrinkage rate allows a fine gap to be formed between the sealing member of the cured product and the substrate or the like due to internal stress. This causes reduction in adhesive strength and also reduction in resistance against moisture permeation.

The cured product of the polymerizable epoxy composition of the present invention has a high refractive index. The refractive index of the cured product is preferably higher than 1.60, more preferably 1.64 or higher, further preferably 1.66 or higher, particularly preferably 1.68 or higher. The refractive index is a measured value using the sodium D line (589 nm). The refractive index can be measured with a known method. In general, the refractive index can be measured by a critical angle method with an Abbe refractometer.

The cured product of the polymerizable epoxy composition of the present invention is preferably transparent in the visible light region. The transparency can be evaluated based on the light transmittance using a UV/visible spectrophotometer. The luminous transmittance of the cured product of the present invention is preferably 30% or more at 450 nm, more preferably 50% or more, further preferably 80% or more. The reason for that is to improve display performance for use as a sealing member of an optical device (including an organic EL element).

The luminous transmittance of a cured product of a polymerizable epoxy composition can be measured by the following procedure.

1) A cured product of a polymerizable epoxy composition is applied onto a substrate and dried to be cured to obtain a cured product having a thickness of 100 μm.

2) The luminous transmittance of the obtained cured product at a wavelength of 450 nm is measured with a UV/visible spectrophotometer (MULTISPEC-1500 made by Shimadzu Corporation).

The cured polymerizable epoxy composition of the present invention can be used as a sealing member. Furthermore, the cured composition is preferably used as a sealing member or an optical material through which light from an optical device passes. Examples of the optical device include an organic EL panel, a liquid crystal display, an LED, an electronic paper, a solar cell, and a CCD. Examples of the optical material include an optical adhesive, an optical film, a hologram material, a photonic crystal, a diffraction grating, a prism, a refractive index distribution lens, an optical fiber, and an optical waveguide film.

Furthermore, the polymerizable epoxy composition of the present invention is preferably used as a sealing material composition (or transparent resin composition for optical material) for a sealing member of a light emitting element (in particular, an organic EL element having a top emission structure). The reason is that the efficiency in extracting emission from an organic EL element is improved, when used as a sealing member of an organic EL element having a top emission structure. Specifically, an organic EL element having a top emission structure includes a transparent cathode electrode layer such as ITO on an organic EL layer. Since ITO has a refractive index of approximately 1.8, a sealing member having an excessively low refractive index which is arranged on the cathode electrode layer reduces the efficiency in extracting emission from an organic EL element.

The polymerizable epoxy composition of the present invention may be manufactured by any optional method, so long as the effect of the present invention is not impaired. For example, a manufacturing method of a polymerizable epoxy composition includes step 1 of mixing epoxy compounds each (including (A1) to (A3)) to form an epoxy mixture, and step 2 of mixing the epoxy mixture and (C) a thiol compound at 30° C. or lower.

Examples of the mixing method include agitating the components charged in a flask, and kneading with a three-roll mill. The (B) curing accelerator and any other optional component are preferably mixed with the mixture produced in step 2.

Step 1 may be performed under heating conditions. In order to mix the epoxy components as uniform as possible, the heating temperature is set corresponding to the softening point of each of the epoxy components.

In step 2, the epoxy mixture and the (C) thiol compound are mixed, for example, under non-heating conditions (30° C. or lower). The reason is to prevent the curing reaction (gelation or the like) of the epoxy mixture and the (C) thiol compound from proceeding. In like manner, the (B) curing accelerator is preferably mixed at 30° C. or lower.

2. Organic EL Device

As described above, the polymerizable epoxy composition of the present invention is useful as a composition for making a sealing member of an organic EL element. In other words, the organic EL device of the present invention includes a display substrate having an organic EL element thereon, a counter substrate to constitute a pair with the display substrate, and a sealing member that is arranged at any place between the display substrate and the counter substrate.

A sealing method to cover an organic EL element is referred to as face sealing. Examples of the face sealing include a method for sealing by filling a space formed between the organic EL element and the counter substrate with a sealing member. On the other hand, sealing by arranging a sealing member at the periphery of the counter substrate is referred to as frame sealing. The polymerizable epoxy composition of the present invention may be used in any one of the sealing members for face sealing and frame sealing, preferably used in the sealing member for face sealing, and more preferably used in the sealing member for face sealing in an organic EL device having a top emission structure.

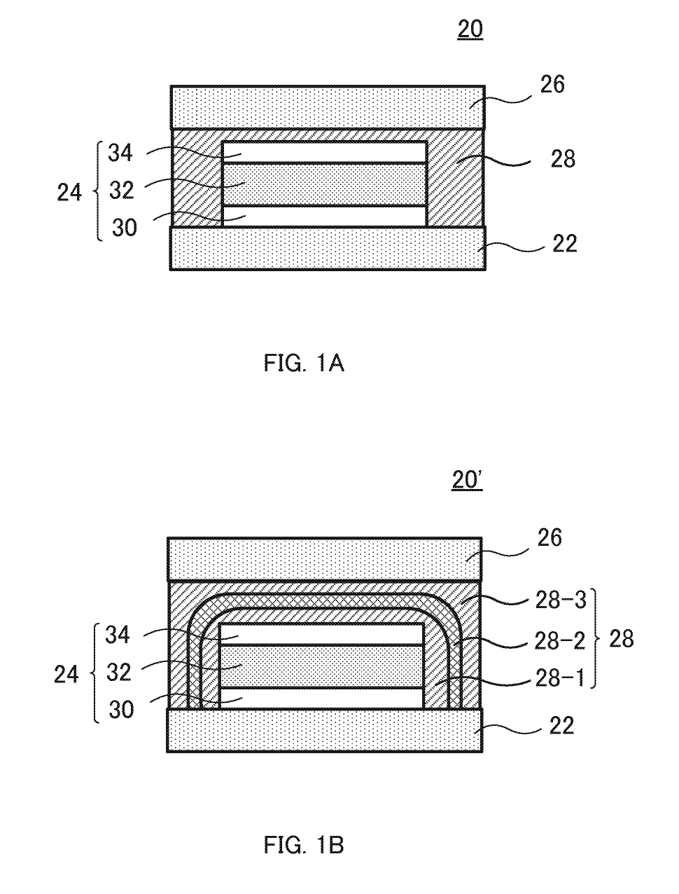

FIG. 1A is a schematic cross-sectional view illustrating a first example of a face sealing type organic EL device. Organic EL device 20 shown in FIG. 1A includes display substrate 22, organic EL element 24, sealing substrate 26, and sealing part 28 for face sealing. Organic EL element 24 includes pixel electrode 30, organic EL layer 32, and counter electrode 34. Sealing part 28 in FIG. 1A is formed into the cured product of the polymerizable epoxy composition. Although not shown in FIG. 1A, counter electrode 34 may be covered with a passivation film of an inorganic composition such as silicon oxide and silicon nitride.

FIG. 1B is a schematic cross-sectional view illustrating a second example of a face sealing type organic EL device. Organic EL device 20′ shown in FIG. 1B includes display substrate 22, organic EL element 24, sealing substrate 26, and sealing part 28 for face sealing. Organic EL element 24 includes pixel electrode 30, organic EL layer 32, and counter electrode 34. Sealing part 28 in FIG. 1B includes resin cured product layer 28-1, passivation layer 28-2 of an inorganic compound such as silicon oxide and silicon nitride, and adhesive resin layer 28-3. Resin cured product layer 28-1 in FIG. 1B may be the cured product of the polymerizable epoxy composition.

The organic EL device may be manufactured by any optional method. For example, organic EL device 20 shown in FIG. 1A may be manufactured by a method including step 1 of applying a sealing material composition to display substrate 22 on which organic EL element 24 is laminated, step 2 of laminating sealing substrate 26 to be paired on display substrate 22 coated with the sealing material composition so as to form a laminated body, and step 3 of curing the sealing material composition (the polymerizable epoxy composition) of the produced laminated body into sealing part 28. Each of the steps may be performed according to a known method. Examples of the method for applying the sealing material composition include screen printing and a method using a dispenser. Since the viscosity of the polymerizable epoxy composition of the present invention is adjusted to 100 to 15000 mPa·s, application can be easily performed. The curing step is performed preferably at 25 to 100° C. for 0.1 to 2 hours.

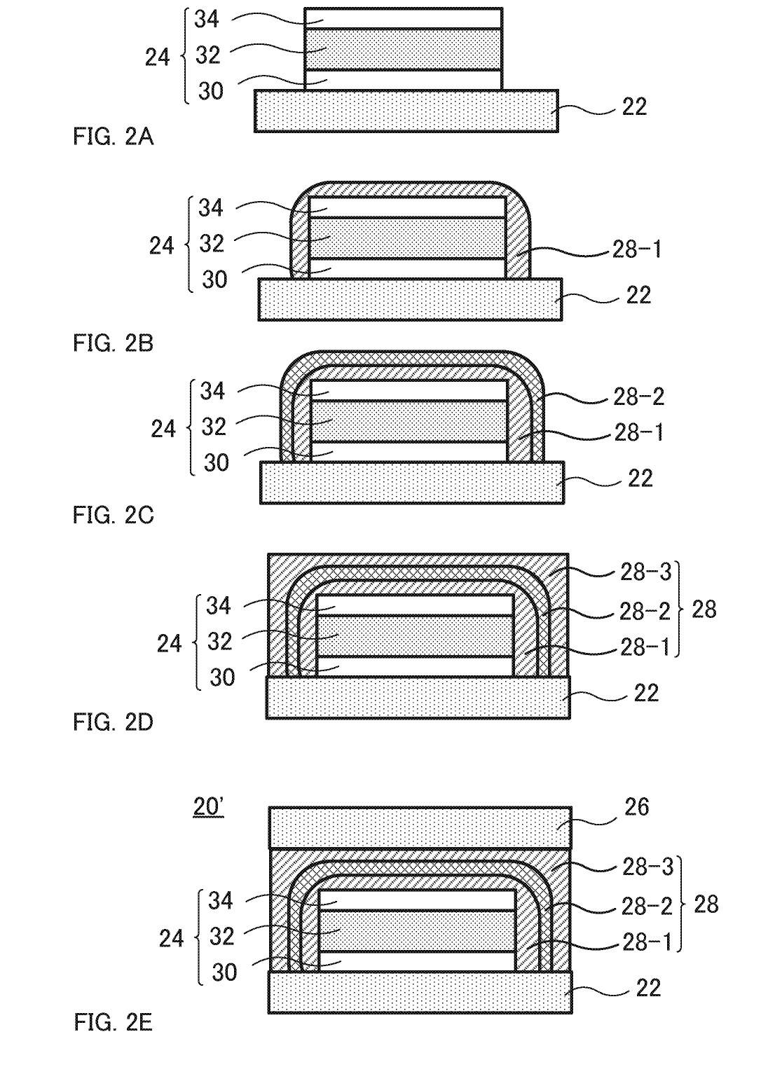

FIGS. 2A to 2E is a schematic diagram illustrating a manufacturing process of organic EL device 20′ shown in FIG. 1B. First, display substrate 22 on which organic EL element 24 is laminated is prepared (FIG. 2A). The organic EL element includes pixel electrode 30, organic EL layer 32, and counter electrode 34, and may further include any other functional layer. Subsequently, a sealing material composition (the polymerizable epoxy composition) is applied on organic EL element 24 laminated on display substrate 22 (so as to cover counter electrode 34), and then cured to form cured product layer 28-1 (FIG. 2B).

Subsequently, passivation layer 28-2 is formed on cured product layer 28-1 (FIG. 2C). Passivation layer (transparent inorganic compound layer) 28-2 may be formed by any optional method including a plasma CVD, sputtering, and the like. Furthermore, passivation layer 28-2 is covered with a resin layer (FIG. 2D), and sealing substrate 26 is superimposed thereon. The resin layer is cured in this state so as to form a adhesive resin layer 28-3 and concurrently allows sealing substrate 26 to be bonded (FIG. 2E). Organic EL device 20′ of the present invention is thus obtained.

The cured product of the epoxy resin composition of the present invention has transparency which is hardly reduced even exposed to plasma. Cured product layer 28-1 of the polymerizable epoxy composition of the present invention can therefore maintain the transparency even though exposed to plasma during film formation of passivation layer 28-2 by plasma CVD or the like. Since an organic EL device is used under conditions exposed to sun light or the like for long hours in many cases, weather resistance is required for the cured product of the face sealing material for an organic EL element. Since the cured product of the epoxy resin composition of the present invention can maintain the transparency even exposed to plasma as described above, it is evident to have high weather resistance.

FIGS. 2A to 2E illustrate a flow in which one organic EL element 24 is formed on display substrate 22 and sealed. Alternatively, a plurality of organic EL elements 24 formed on display substrate 22 may be sealed in one flow, in a similar procedure.

The organic EL device of the present invention may be used for an organic EL display panel. In an organic EL display panel, organic EL devices are usually arranged on a substrate in a matrix form.

### EXAMPLES

The present invention is described in more details with reference to Examples. The scope of the present invention is not interpreted as limited by the Examples.

Polymerizable epoxy compositions were manufactured using the following components.

(A1) S-containing epoxy resin: TBBT epoxy (which can be synthesized by a method described in Japanese Patent Application Laid-Open No. 10-324858), refractive index: 1.68

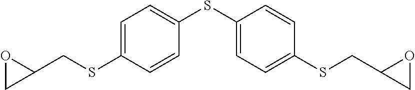 [SMILES: c1cc(Sc2ccc(SCC3CO3)cc2)ccc1SCC1CO1]

(A2) Low softening point epoxy: EP3950S (made by Adeka Corporation), Aniline-type trifunctional epoxy, liquid at room temperature

(A2) Low softening point epoxy: VG3101 (made by Printec Corporation), softening point: 38 to 46° C.

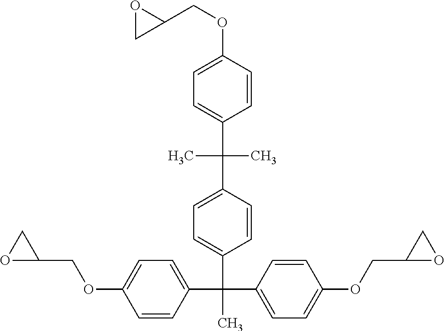 [SMILES: CC(C)(c1ccc(OCC2CO2)cc1)c1ccc(C(C)(c2ccc(OCC3CO3)cc2)c2ccc(OCC3CO3)cc2)cc1]

(A2) Low softening point epoxy: YL983U (made by Mitsubishi Chemical Corporation), bisphenol F type epoxy, liquid at room temperature

(A3) Fluorene epoxy: PG-100 (made by Osaka Gas Chemicals Co., Ltd.)

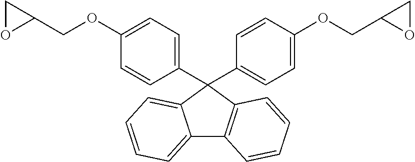 [SMILES: c1ccc2c(c1)-c1ccccc1C2(c1ccc(OCC2CO2)cc1)c1ccc(OCC2CO2)cc1]

(B) Curing accelerator: 2E4MZ (2-ethyl-4-methyl imidazole)

(B) Curing accelerator: TMDPO (2,4,6-trimethylbenzoyl diphenylphosphine oxide)

(C) Thiol compound: GST (made by Mitsui Chemicals, Inc.)

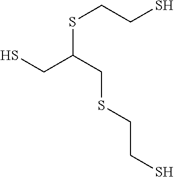 [SMILES: SCCSCC(CS)SCCS]

(C) Thiol compound: FSH (made by Mitsui Chemicals, Inc.)

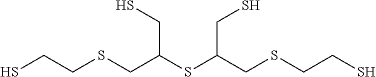 [SMILES: SCCSCC(CS)SC(CS)CSCCS]

(C) Thiol compound: OPST (made by Mitsui Chemicals, Inc.)

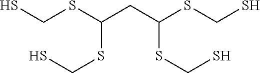 [SMILES: SCSC(CC(SCS)SCS)SCS]

(C) Thiol compound: TBBT (4,4′-thio-bis-(benzenethiol))

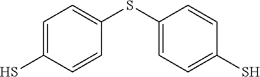 [SMILES: Sc1ccc(Sc2ccc(S)cc2)cc1]

Acid anhydride: Rikacid MH700 (made by New Japan Chemical Co., Ltd.)

Acrylic acid: acrylic acid (made by Tokyo Chemical Industry Co., Ltd.)

### Example 1

Into a flask, 50 parts by mass of TBBT epoxy ((A1) S-containing epoxy), 20 parts by mass of EP3950S ((A2) low softening point epoxy), 30 parts by mass of PG-100 ((A3) fluorene epoxy) were charged, and mixed while heating. Into the mixture, 52 parts by mass of GST ((C) thiol compound) was added and mixed at room temperature. Furthermore, 0.4 parts by mass of 2E4MZ ((B) curing accelerator) was added to the mixture and agitated at room temperature so as to produce a polymerizable epoxy composition.

### Examples 2 to 9

As shown in Table 1, the quantity of the (A1) S-containing epoxy, the type and the quantity of the (A2) low softening point epoxy, the quantity of the (A3) fluorene epoxy, and the type and the quantity of the (C) thiol compound were changed to obtain polymerizable epoxy compositions by the same procedure as in Example 1.

### Comparative Example 1

According to the composition described in Table 2, a polymerizable epoxy composition was obtained by the same procedure as in Example 1. Instead of the (C) thiol compound, an acid anhydride was compounded.

### Comparative Example 2

Using the composition described in Table 2, a polymerizable epoxy composition was obtained by the same procedure as in Example 1. No (C) thiol compound was compounded.

### Comparative Examples 3 and 4

Using the composition described in Table 2, polymerizable epoxy compositions were obtained by the same procedure as in Example 1. No (A1) S-containing epoxy was compounded.

### Comparative Example 5

Using the composition described in Table 2, a polymerizable epoxy composition was obtained by the same procedure as in Example 1. No (A2) low softening point epoxy was compounded.

### Comparative Example 6

Using the composition described in Table 2, a polymerizable epoxy composition was obtained by the same procedure as in Example 1. No (A2) low softening point epoxy or (A3) fluorene epoxy was compounded.

### Comparative Example 7

Using the composition described in Table 2, a polymerizable epoxy composition was obtained by the same procedure as in Example 1. No (A2) low softening point epoxy, (A3) fluorene epoxy or (C) thiol compound was compounded, while acrylic acid was compounded.

### Comparative Example 8

Using the composition described in Table 2, a polymerizable epoxy composition was obtained by the same procedure as in Example 1. No (A2) low softening point epoxy or (A3) fluorene epoxy was compounded.

The polymerizable epoxy compositions obtained in Examples 1 to 9 and Comparative Examples 1 to 8 were evaluated on the following items. The evaluation results are described in Table 1 and Table 2.

[State of Composition]

Visual observation was performed to determine whether a polymerizable epoxy composition is transparent and colorless.

[Viscosity of Composition]

The viscosity at 25° C. of a polymerizable epoxy composition was measured at a rotation speed of 60 rpm with a B type viscometer (BL type Viscometer/rotor No. 4, made by Toki Sangyo Co., Ltd).

Each of the polymerizable epoxy compositions obtained in Examples 1 to 9 and Comparative Examples 1 to 6 was cast into a mold and heated at 90° C. for 1 hour so as to produce a cured product having a thickness of 0.2 mm. The polymerizable epoxy composition obtained in Comparative Example 7 was cast into a mold, exposed to UV light of 10 mW/cm² for 5 minutes, and further heated at 60° C. for 2 hours, so as to produce a cured product having a thickness of 0.2 mm. The polymerizable epoxy composition obtained in Comparative Example 8 was not able to be cured.

[State of Cured Product]

Visual observation was performed to determine whether the produced cured product is transparent and colorless.

[Curing Shrinkage Rate]

The curing shrinkage rate was obtained by applying the specific gravity of the composition before curing and the specific gravity of the cured product after curing into the following equation.

Curing shrinkage rate (%)={(specific gravity of cured product−specific gravity of uncured composition)/specific gravity of cured product}×100

[Refractive Index of Cured Product]

The refractive index of the produced cured product was measured under irradiation of the sodium D line (589 nm) using a refractometer (multi-wavelength Abbe refractometer DR-M4 made by Atago Co., Ltd).

[Glass Transition Temperature of Cured Product]

The linear expansion coefficient of the produced cured product was measured under a rate of temperature rise of 5° C./min with TMA (TMA/SS6000 made by Seiko Instruments Inc.). Tg was obtained from the inflection point thereof.

[Haze Value of Cured Product]

The haze value (%) of the produced cured product was measured with a haze meter (model name: TC-H3DPK, made by Tokyo Denshoku Co., Ltd.). The cured product was then placed in a plasma cleaner (model name: PDC210, parallel flat stage plate type, made by Yamato Scientific Co., Ltd.) so as to be irradiated with plasma for 20 minutes at an oxygen flow rate of 20 mL/min and with an RF output of 500 W. After plasma irradiation, the haze value (%) of the cured product layer was measured with a haze meter (model name: TC-H3DPK, made by Tokyo Denshoku Co., Ltd.).

The evaluation on the change in haze through plasma irradiation allows for determination of suitability for use as a face sealing agent in a manufacturing method of an organic EL device including a step of irradiating a cured product of a face sealing agent with plasma, and also allows for accelerated evaluation of weather resistance.

[Water Content in Composition]

The water content of the polymerizable epoxy compositions were measured by the Karl Fischer method. Examples 1 to 9 and Comparative Examples 1 to 8 each had a water content rate of 0.1% by weight or less.

TABLE 1

| | | | Example 1 | Example 2 | Example 3 | Example 4 | Example 5 |
|---|---|---|---|---|---|---|---|
| Composition | (A1) S-containing | Part by weight | 50 | 50 | 50 | 50 | 50 |
| | epoxy | | | | | | |
| | (A2) Low | Component | EP-3950S | EP-3950S | EP-3950S | EP-3950S | VG3101 |
| | softening point | | (trifunctional) | (trifunctional) | (trifunctional) | (trifunctional) | (trifunctional) |
| | epoxy | Part by weight | 20 | 20 | 20 | 40 | 20 |
| | (A3) Fluorene | Component | PG-100 | PG-100 | PG-100 | PG-100 | PG-100 |
| | epoxy | Part by weight | 30 | 30 | 30 | 10 | 30 |
| | (B) Curing | Component | 2E4MZ | 2E4MZ | 2E4MZ | 2E4MZ | 2E4MZ |
| | accelerator | Part by weight | 0.4 | 0.4 | 0.4 | 0.4 | 0.4 |
| | (C) Thiol | Component | GST | FSH | OPST | OPST | GST |
| | compound | Part by weight | 52 | 55 | 54 | 65 | 42 |
| | Acid anhydride | Part by weight | — | — | — | — | — |
| | Acrylic acid | Part by weight | — | — | — | — | — |

| | | | | | | |
|---|---|---|---|---|---|---|
| Evaluation | State of composition | Transparent | Transparent | Transparent | Transparent | Transparent |
| | | and colorless | and colorless | and colorless | and colorless | and colorless |
| | Viscosity of composition (mPa · s) | 460 | 1400 | 14000 | 1000 | 1400 |
| | Curing conditions | 90° C./1 h | 90° C./1 h | 90° C./1 h | 90° C./1 h | 90° C./1 h |
| | State of cured product | Transparent | Transparent | Transparent | Transparent | Transparent |
| | | and colorless | and colorless | and colorless | and colorless | and colorless |
| | Curing shrinkage rate (%) | 6.5 | 6.3 | 6.3 | — | — |
| | Refractive index (D line) | 1.687 | 1.688 | 1.699 | 1.696 | 1.685 |
| | Tg of cured product (° C.) | 56 | 69 | 78 | 74 | 60 |
| | Haze before oxygen plasma | 1.0 | 0.3 | 0.3 | 0.3 | 0.7 |
| | irradiation (%) | | | | | |
| | Haze after oxygen plasma | 0.4 | 1.5 | 1.1 | 1.6 | 2.3 |
| | irradiation (%) | | | | | |

| | | | Example 6 | Example 7 | Example 8 | Example 9 |
|---|---|---|---|---|---|---|
| Composition | (A1) S-containing | Part by weight | 50 | 70 | 50 | 50 |
| | epoxy | | | | | |
| | (A2) Low | Component | YL-983U | EP-3950S | EP-3950S | EP-3950S |
| | softening point | | (bifunctional) | (trifunctional) | (trifunctional) | (trifunctional) |
| | epoxy | Part by weight | 20 | 30 | 50 | 50 |
| | (A3) Fluorene | Component | PG-100 | — | — | — |
| | epoxy | Part by weight | 30 | — | — | — |
| | (B) Curing | Component | 2E4MZ | 2E4MZ | 2E4MZ | 2E4MZ |
| | accelerator | Part by weight | 0.4 | 0.4 | 0.4 | 0.4 |
| | (C) Thiol | Component | GST | GST | GST | FSH |
| | compound | Part by weight | 44 | 61 | 69 | 73 |
| | Acid anhydride | Part by weight | — | — | — | — |
| | Acrylic acid | Part by weight | — | — | — | — |

| | | | | | |
|---|---|---|---|---|---|
| Evaluation | State of composition | Transparent | Transparent | Transparent | Transparent |
| | | and colorless | and colorless | and colorless | and colorless |
| | Viscosity of composition (mPa · s) | 700 | 150 | 190 | 380 |
| | Curing conditions | 90° C./1 h | 90° C./1 h | 90° C./1 h | 90° C./1 h |
| | State of cured product | Transparent | Transparent | Transparent | Transparent |
| | | and colorless | and colorless | and colorless | and colorless |
| | Curing shrinkage rate (%) | 6.1 | 6.0 | — | — |
| | Refractive index (D line) | 1.684 | 1.690 | 1.677 | 1.679 |
| | Tg of cured product (° C.) | 51 | 42 | 48 | 59 |
| | Haze before oxygen plasma | 0.3 | 0.5 | — | — |
| | irradiation (%) | | | | |
| | Haze after oxygen plasma | 2.6 | 4.2 | — | — |
| | irradiation (%) | | | | |

TABLE 2

| | | | Comparative | Comparative | Comparative | Comparative |
|---|---|---|---|---|---|---|
| | | | Example 1 | Example 2 | Example 3 | Example 4 |
| Composition | (A1) S-containing | Part by weight | 50 | 50 | — | — |
| | epoxy | | | | | |
| | (A2) Low | Component | EP-3950S | EP-3950S | YL-983U | YL-983U |
| | softening point | | (trifunctional) | (trifunctional) | (bifunctional) | (bifunctional) |
| | epoxy | Part by weight | 30 | 30 | 50 | 50 |
| | (A3) Fluorene | Component | PG-100 | PG-100 | PG-100 | PG-100 |
| | epoxy | Part by weight | 20 | 20 | 50 | 50 |
| | (B) Curing | Component | 2E4MZ | 2E4MZ | 2E4MZ | 2E4MZ |
| | accelerator | Part by weight | 3 | 3 | 0.4 | 0.4 |
| | (C) Thiol | Component | — | — | GST | OPST |
| | compound | Part by weight | — | — | 44 | 45 |
| | Acid anhydride | Part by weight | 107 | — | — | — |
| | Acrylic acid | Part by weight | — | — | — | — |

| | | | | | |
|---|---|---|---|---|---|
| Evaluation | State of composition | Transparent | Transparent | Transparent | Transparent |
| | | and colorless | and colorless | and colorless | and colorless |
| | Viscosity of composition (mPa · s) | 370 | 2030 | 5300 | 64000 |
| | Curing conditions | 90° C./1 h | 90° C./1 h | 90° C./1 h | 90° C./1 h |
| | State of cured product | Transparent | Brown | Transparent | Transparent |
| | | and colorless | | and colorless | and colorless |
| | Curing shrinkage rate (%) | — | — | 5.6 | — |
| | Refractive index (D line) | 1.573 | 1.660 | 1.653 | 1.670 |
| | Tg of cured product (° C.) | 119 | 71 | 60 | 104 |
| | Haze before oxygen plasma | 0.2 | 0.4 | 0.3 | — |
| | irradiation (%) | | | | |
| | Haze after oxygen plasma | 3.1 | 0.7 | 1.4 | — |
| | irradiation (%) | | | | |

| | | | Comparative | Comparative | Comparative | Comparative |
|---|---|---|---|---|---|---|
| | | | Example 5 | Example 6 | Example 7 | Example 8 |
| Composition | (A1) S-containing | Part by weight | 50 | 100 | 100 | 75 |
| | epoxy | | | | | |
| | (A2) Low | Component | — | — | — | — |
| | softening point | | | | | |
| | epoxy | Part by weight | — | — | — | — |
| | (A3) Fluorene | Component | PG-100 | — | — | — |
| | epoxy | Part by weight | 50 | — | — | — |
| | (B) Curing | Component | 2E4MZ | 2E4MZ | TMDPO | 2E4MZ |
| | accelerator | Part by weight | 0.4 | 0.4 | 4.2 | 0.4 |
| | (C) Thiol | Component | GST | GST | — | TBBT |
| | compound | Part by weight | 41 | 45 | — | 25 |
| | Acid anhydride | Part by weight | — | — | — | — |
| | Acrylic acid | Part by weight | — | — | 40.5 | — |

| | | | | | |
|---|---|---|---|---|---|
| Evaluation | State of composition | White | White | Transparent | Paste form |
| | | turbidity | turbidity | and colorless | |
| | Viscosity of composition (mPa · s) | — | — | 400 | — |
| | Curing conditions | 90° C./1 h | 90° C./1 h | UV + 60° C./2 h | — |
| | State of cured product | White | White | Transparent | |
| | | turbidity | turbidity | and colorless | |
| | Curing shrinkage rate (%) | 5.8 | — | 10.5 | |
| | Refractive index (D line) | 1.692 | 1.699 | 1.648 | |
| | Tg of cured product (° C.) | 57 | <30 | 112 | |
| | Haze before oxygen plasma | — | — | Failed curing | |
| | irradiation (%) | | | | |
| | Haze after oxygen plasma | — | — | — | — |
| | irradiation (%) | | | | |

### Comparative Examples 9 and 10

In a flask flushed with nitrogen, 100 parts by weight of an epoxy resin having a composition described in Table 3, 85 parts by weight of acid anhydride, 4 parts by weight of a silane coupling agent, and a curing accelerator with parts by weight as described in Table 3 were mixed and agitated to produce a face sealing agent.

The viscosity of each of the face sealing agents obtained in Comparative Examples 9 and 10 was measured. The viscosity at 25° C. of the polymerizable epoxy compositions was measured with an E type viscometer (Digital Rheometer Model DII-III Ultra, made by Brookfield Engineering Laboratories, Inc.). Measurement results are described in Table 1.

The curability of each of the face sealing agents obtained in Comparative Examples 9 and 10 was evaluated by the following method. Each of the face sealing agents was inserted between two sheets of NaCl crystal plates (thickness: 5 mm) so as to prepare a sample. The face sealing agent was sealed between the two sheets of NaCl crystal plates (2 cm square), and the distance between the NaCl crystal plates was adjusted to 15 μm. The infrared transmission spectrum was measured on the sample before and after heat treatment at 100° C. for 30 minutes with an FT-IR measurement apparatus. Based on the obtained spectrum, the height of an absorption peak (at near 910 cm⁻¹) due to antisymmetric ring stretching of an epoxy group was divided by the height of an absorption peak (at near 1600 cm⁻¹) due to C—C stretching in a benzene ring for normalization. The reaction rate of the epoxy group was calculated from the reduction degree of the epoxy group-derived peak due to the heat treatment.

A value of {(x1−x2)/x1}×100(%) was calculated as the epoxy conversion rate, where x1 represents the normalized value of the epoxy group peak before heat treatment, and x2 represents the normalized value of the epoxy group peak after heat treatment. An epoxy conversion rate of 80% or higher was evaluated as “good.”

Preparation of Cured Product Layer

Each of the face sealing agents obtained in Comparative Examples 9 and 10 was applied by printing (5 cm by 5 cm by 3 μm thick) on a glass substrate (7 cm by 7 cm by 0.7 μm thick) cleaned by ozone in advance with a screen printing machine (Screen Printer Model 2200 made by Mitani Micronics Co., Ltd.).

The printed glass substrate was heated on a hot plate heated to 100° C. for 30 minutes so as to form a cured product layer.

The haze value (%) of the cured product layer was measured with a haze meter (model name: TC-H3DPK, made by Tokyo Denshoku Co., Ltd.). The glass substrate having the cured product layer was then placed in a plasma cleaner (model name: PDC210, parallel flat stage plate type, made by Yamato Scientific Co., Ltd.) so as to be irradiated with plasma for 20 minutes at an oxygen flow rate of 20 mL/min and with an RF output of 500 W. After plasma irradiated, the haze value (%) of the cured product layer was measured with a haze meter (model name: TC-H3DPK, made by Tokyo Denshoku Co., Ltd.). Each of the measured haze values is described in Table 1.

TABLE 3

| | | Molecular | Comparative | Comparative |
|---|---|---|---|---|
| | | weight | Example 9 | Example 10 |
| Epoxy resin | YL-983U | 338 | 60 | 60 |
| | VG-3101L | 592 | 40 | 40 |
| Acid anhydride | Rikacid MH-700 | | 85 | 85 |
| Silane coupling | KBM-403 | | 4 | 4 |
| agent | | | | |
| Curing | 2E4MZ | 110 | | 3 |
| accelerator | SA-810 | 318 | 3 | |

| Equivalent ratio of tertiary amino group/ | | 0.0489 | 0.01691 |
|---|---|---|---|
| epoxy group in curing accelerator | | | |
| Water content (mass ppm) | | 10 | 10 |
| Physical | Curability at 100° C. | good | good |
| properties | Viscosity (Pa · s) | 4.739 | 2.973 |
| | Haze (before plasma | 0 | 0.1 |
| | irradiation) | | |
| | Haze (after plasma | 54.9 | 58.2 |
| | irradiation) | | |

YL-983U: bisphenol F type epoxy resin (made by Japan Epoxy Resins Co., Ltd.)
VG-3101L: trifunctional epoxy resin, molecular weight: 592, (made by Printec Corporation)
MH-700: mixture of methyl hexahydrophthalic anhydride and hexahydrophthalic anhydride (made by New Japan Chemical Co., Ltd.)
KBM-403: 3-glycidoxypropyltrimethoxysilane, molecular weight: 236 (made by Shin-Etsu Chemical Co., Ltd.)
2E4MZ: 2-phenyl-4-methyl imidazole (Curezol 2P4MZ made by Shikoku Chemicals Corporation)
SA-810: diazacyclo undecene phthalate (made by San-Apro Ltd.)

Each of the polymerizable epoxy compositions obtained in Examples was transparent and colorless, having a reduced viscosity (14000 mPa·s or lower). Furthermore, it was found that the cured products thereof have a high refractive index (higher than 1.67). In contrast, it was found that the polymerizable epoxy compositions obtained in Comparative Examples 1 to 4 have a low refractive index (1.67 or lower). The polymerizable epoxy compositions obtained in Comparative Examples 5 and 6 had white turbidity, and the cured products thereof also had white turbidity. The polymerizable epoxy composition obtained in Comparative Example 7 had a high curing shrinkage rate and a refractive index of 1.65 or lower. No thin film was able to be formed due to insufficient curing resulting from oxygen inhibition during thin film curing. The polymerizable epoxy composition obtained in Comparative Example 8 was in paste form, and difficult to be cured.

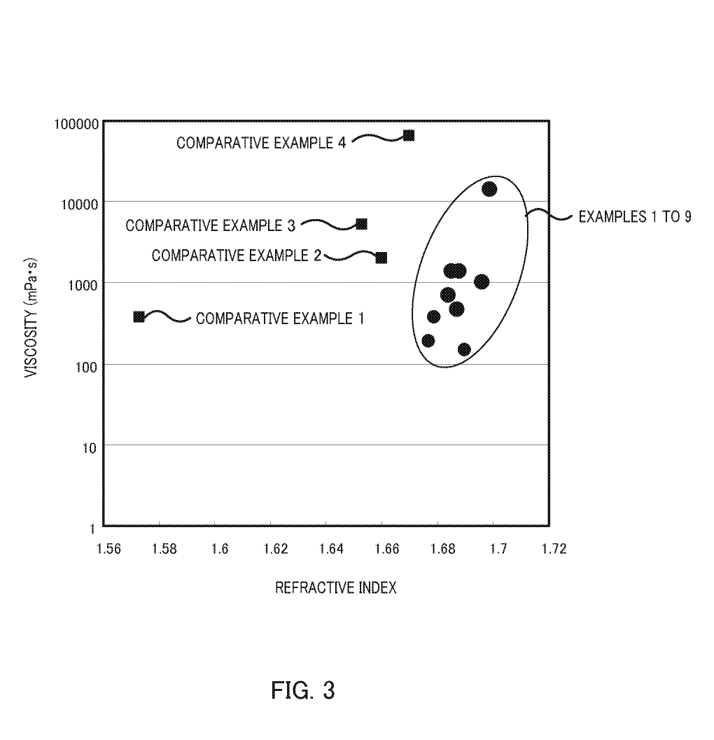

FIG. 3 is a graph plotting the viscosity of the polymerizable epoxy compositions in Examples 1 to 9 and the polymerizable epoxy compositions in Comparative Examples 1 to 4 and the refractive index of the cured products thereof. As illustrated in FIG. 3, it was found that the polymerizable epoxy compositions obtained in Examples maintain low viscosity and have high refractive index of the cured products thereof.

The cured products of the polymerizable epoxy compositions obtained in Examples 1 to 6 had a glass transition temperature (51° C. to 78° C.) relatively higher than the glass transition temperature (42° C. to 59° C.) of the polymerizable epoxy compositions obtained in Examples 7 to 9. This means that the addition of a fluorene epoxy resin allows for production of an epoxy resin cured product having good heat resistance.

The cured products of the polymerizable epoxy compositions obtained in Examples 1 to 9 have higher plasma resistance compared to those in Comparative Examples 9 and 10. This means that the composition of the present invention is suitable for production of an organic EL device exposed to plasma and the cured product of the composition of the present invention has excellent weather resistance.

### INDUSTRIAL APPLICABILITY

The polymerizable epoxy composition of the present invention has a low viscosity even under high shear stress, allowing for easy forming with printing or the like. Yet, the cured product thereof has a high refractive index. The composition is therefore suitable for use as a sealing material of an optical device, in particular, a light emitting device.

### REFERENCE SIGNS LIST

20 and 20′ Organic EL device
22 Display substrate
24 Organic EL element
26 Sealing substrate
28 Sealing part
28-1 Cured product layer
28-2 Passivation layer
28-3 Adhesive resin layer
30 Pixel electrode
32 Organic EL layer
34 Counter electrode

1. A polymerizable epoxy composition comprising:
(A1) a S-containing epoxy compound represented by the following general formula (i) having a refractive index of 1.66 to 1.80: 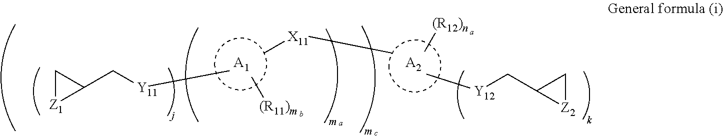
wherein,
A₁ and A₂ each independently represent a benzene ring or a 1,3,5-triazine ring;
X₁₁ each independently represents —S—, —SO₂—, —O—, or —C(R₂₁)₂—, where R₂₁ each independently represents a hydrogen atom or a C₁₋₃ alkyl group
Y₁₁ and Y₁₂ each independently represent —O— or —S—;
Z₁ and Z₂ each independently represent —O— or —S—;
R₁₁ and R₁₂ each independently represent a C₁₋₆ alkyl group or a halogen group;
mₐ represents any integer of 0 to 10;
m_{c} represents an integer of 1 to 5 when A₂ is a benzene ring, and represents 1 or 2 when A₂ is a 1,3,5-triazine ring;
m_{b} and nₐ each independently represent an integer of 0 to 4 when A₁ or A₂ is a benzene ring, and each independently represent 0 or 1 when A₁ or A₂ is a 1,3,5-triazine ring;
j and k each independently represent an integer of 1 to 5 when A₁ or A₂ is a benzene ring, and each independently represent 1 or 2 when A₁ or A₂ is a 1,3,5-triazine ring;
the sum of m_{b} and j is 5 or less when A₁ is a benzene ring, and 2 or less when A₁ is a 1,3,5-triazine ring;
the sum of nₐ, k, and m_{c} is 6 or less when A₂ is a benzene ring, and 3 or less when A₂ is a 1,3,5-triazine ring;
at least one group represented by Y₁₁, Y₁₂, Z₁, and Z₂ is —S— when mₐ is 0; and
at least one group represented by X₁₁, Y₁₁, Y₁₂, Z₁, and Z₂ is a S-containing group when mₐ is 1 to 10;
(A2) an epoxy compound having a softening point of 70° C. or lower (except the (A1) S-containing epoxy compound);
(B) a curing accelerator; and
(C) a thiol compound having two or more thiol groups in one molecule;
the polymerizable epoxy composition having a viscosity of 100 to 15000 mPa·s at 25° C. and 60 rpm measured with a B type viscometer.

2. The polymerizable epoxy composition according to claim 1, wherein the S-containing epoxy compound represented by general formula (i) is a S-containing epoxy compound represented by the following general formula (1): 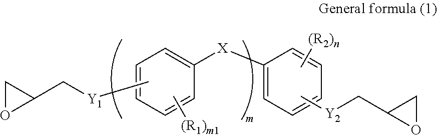
wherein,
X represents —S— or —SO₂—;
Y₁ and Y₂ each independently represent —O— or —S—;
m represents any integer of 0 to 10;
ml and n each independently represent any integer of 0 to 4;
R₁ and R₂ each independently represent a C₁₋₅ alkyl group or a halogen group; and
at least one of Y₁ and Y₂ is —S— when m is 0.

3. The polymerizable epoxy composition according to claim 1, further comprising (A3) a fluorene epoxy compound represented by the following general formula (2) or general formula (3): 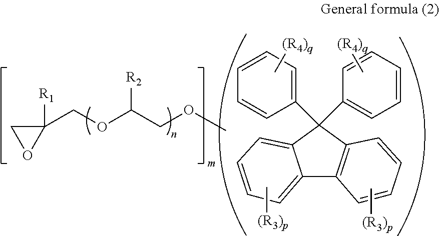
wherein,
R₁ each independently represents a hydrogen atom or a methyl group;
R₂ each independently represents a hydrogen atom or a methyl group;
R₃ each independently represents a C₁₋₅ alkyl group;
R₄ each independently represents a C₁₋₅ alkyl group;
m represents an integer of 2 or more;
n each independently represents an integer of 0 to 3;
p each independently represents an integer of 0 to 4; and
q each independently represents an integer of 0 to 5; and 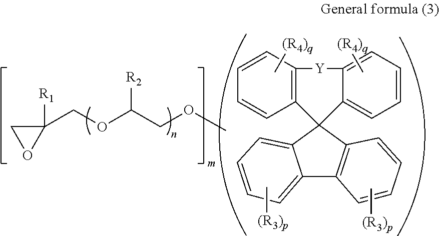
wherein,
Y represents a single bond, an oxygen atom, or a sulfur atom;
q each independently represents an integer of 0 to 4; and
R₁ to R₄, m, n, and p are defined as in general formula (2).

4. The polymerizable epoxy composition according to claim 3, wherein the (A2) epoxy compound is at least one epoxy compound selected from the group consisting of a bisphenol A epoxy compound, a bisphenol F epoxy compound, an amino epoxy compound, and an epoxy compound represented by the following general formula (4): 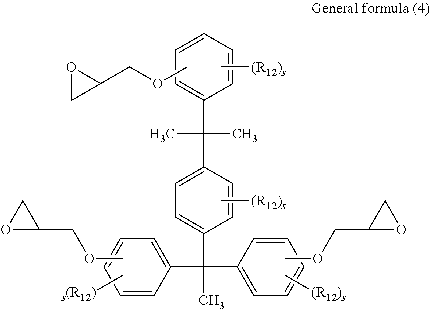
wherein,
R₁₂ each independently represents a C₁₋₅ alkyl group or a halogen atom; and
s represents 0 to 4.

5. The polymerizable epoxy composition according to claim 3, wherein the (A2) epoxy compound is a trifunctional epoxy compound.

6. The polymerizable epoxy composition according to claim 3, wherein the (C) thiol compound has
a thiol equivalent of 80 to 100 g/eq and
a sulfur content rate of 50 to 80%.

7. The polymerizable epoxy composition according to claim 3, wherein the (C) thiol compound has a molecular weight of 140 to 500.

8. The polymerizable epoxy composition according to claim 3, wherein the content of the (A1) S-containing epoxy compound is 50 parts by mass or more relative to 100 parts by mass of the epoxy compounds contained in the polymerizable epoxy composition.

9. The polymerizable epoxy composition according to claim 3, wherein a molar ratio of an epoxy group and an thiol group contained in the polymerizable epoxy composition is 1:0.9 to 1.1.

10. The polymerizable epoxy composition according to claim 3, having a water content rate of 0.1% by mass or less.

11. A transparent resin for an optical material, comprising a polymerizable epoxy composition according to claim 3.

12. A face sealing agent for an organic EL element, comprising a polymerizable epoxy composition according to claim 3.

13. A cured product of a polymerizable epoxy composition according to claim 3, having a refractive index of 1.68 or higher.

14. An organic EL device comprising a display substrate having an organic EL element thereon, a counter substrate to constitute a pair with the display substrate, and a sealing member that is interposed between the display substrate and the counter substrate and is filled in the space formed between the organic EL element and the counter substrate,
wherein the sealing member is a cured product of a polymerizable epoxy composition according to claim 3.

15. An organic EL device comprising an organic EL element, a sealing member in contact with the organic EL element, and a passivation membrane in contact with the sealing member,
wherein the sealing member is a cured product of a polymerizable epoxy composition according to claim 3.

16. An organic EL display panel comprising an organic EL device according to claim 14.

17. A manufacturing method of an organic EL device comprising:
a first step of forming an organic EL element on a display substrate;
a second step of sealing the organic EL element with a polymerizable epoxy composition according to claim 3;
a third step of laminating a counter substrate on the display substrate through the composition; and
a fourth step of curing the composition to form a sealing part.

18. A manufacturing method of an organic EL device comprising:
a first step of forming an organic EL element on a substrate;
a second step of sealing the organic EL element with a polymerizable epoxy composition according to claim 3;
a third step of curing the composition to form a sealing part; and
a fourth step of forming a passivation membrane on the sealing part.

19. The polymerizable epoxy composition according to claim 2, further comprising (A3) a fluorene epoxy compound represented by the following general formula (2) or general formula (3): 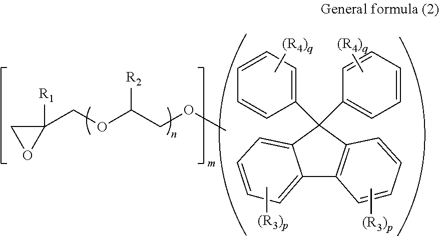
wherein,
R₁ each independently represents a hydrogen atom or a methyl group;
R₂ each independently represents a hydrogen atom or a methyl group;
R₃ each independently represents a C₁₋₅ alkyl group;
R₄ each independently represents a C₁₋₅ alkyl group;
m represents an integer of 2 or more;
n each independently represents an integer of 0 to 3;
p each independently represents an integer of 0 to 4; and
q each independently represents an integer of 0 to 5; and 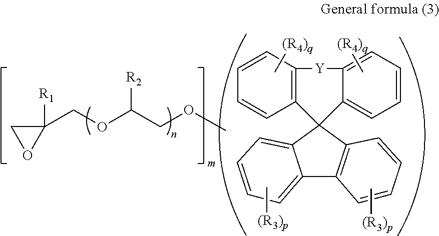
wherein,
Y represents a single bond, an oxygen atom, or a sulfur atom;
q each independently represents an integer of 0 to 4; and
R₁ to R₄, m, n, and p are defined as in general formula (2).

20. An organic EL display panel comprising an organic EL device according to claim 15.
